(19) United States
(12) Patent Application Publication
(10) Pub. No.: US 2008/0179182 A1
(43) Pub. Date: Jul. 31, 2008

(54) Method for fabricating a Micro-Electromechanical device

(75) Inventors: Khier Remadna, Austin, TX (US); James Hunter, Campbell, CA (US); Joshua Lu, Austin, TX (US); Gregory Beach, Georgetown, TX (US)

Correspondence Address: WILLIAM NUTTLE, P.O. BOX 4240, FOSTER CITY, CA, 94404, US

(73) Assignee: Silicon Light Machines Corporation

(21) Appl. No.: 12/011,934

(22) Filed: Jan. 30, 2008

Related U.S. Application Data
(60) Provisional application No. 60/898,352, filed on Jan. 30, 2007.

(51) Int. Cl. C23C 14/34; H01B 13/00

(52) U.S. Cl. 204/192.1; 216/13

(57) ABSTRACT

A method is provided for fabricating micro-electromechanical devices. Generally, the method includes: (i) forming a device layer over a sacrificial layer on a surface of a substrate; (ii) patterning the device layer to form a number of ribbons each including a long axis parallel to the surface of the substrate and a middle section between support structures at both ends of the ribbon; (iii) partially removing the sacrificial layer to undercut the number of ribbons; (iv) forming a reflective coating of a reflective material on the number of ribbons; and (v) releasing the middle section of at least one of the number of ribbons by removing the sacrificial layer. Undercutting the ribbons prior to forming the reflective coating reduces build-up of material on sidewalls of the sacrificial layer facilitating release of the ribbons. Other embodiments are also disclosed.

### CROSS-REFERENCE TO RELATED APPLICATIONS

The present application claims the benefit of priority under 35 U.S.C. 119(e) to U.S. Provisional Patent Application Ser. No. 60/898,352, entitled “Aluminum Deposition with No Sidewall Deposition,” filed Jan. 30, 2007, which application is hereby incorporated by reference in its entirety.

### TECHNICAL FIELD

The present invention relates generally to methods for manufacturing micro-scale and nano-scale electronic and electromechanical devices, and more particularly but not exclusively to a method for forming metallic surfaces on ribbons such as employed in light modulators.

### BACKGROUND OF THE INVENTION

The fabrication of micro-electronic and mechanical devices, such as micro electromechanical systems (MEMS) and optoelectronic devices, typically involves depositing and patterning conducting, semi-conducting and insulating or dielectric layers on a substrate. Basic steps include depositing one or more layers on the substrate, usually a silicon wafer, forming a patterned mask layer over a top layer on the substrate, and etching exposed portions of the one or more of the layers, and possibly into the underlying substrate or layers, using standard wet and/or dry etching techniques.

One well known type of MEMs is a ribbon-type spatial light modulator (SLM), such as a Grating Light Valve (GLV™) commercially available from Silicon Light Machines, Inc., of San Jose, Calif. A block diagram of a perspective view of a ribbon-type spatial light modulator SLM is shown in FIG. 1. Referring to FIG. 1, a ribbon-type spatial light modulator 100 generally includes a number of ribbons 102a, 102b, each including a light reflective surface 104 supported over a surface 106 of a substrate 108. One or more of the ribbons 102a are deflectable toward the substrate 108 to form an addressable diffraction grating with adjustable diffraction strength. The ribbons are 102a deflected towards base electrodes (not shown in this figure) formed in or on the substrate 108 by electrostatic forces when a voltage is applied between the deflectable ribbons 102a and the base electrodes. The applied voltages are controlled by drive electronics (not shown in this figure), which may be integrally formed in or on the surface 106 of the substrate 108 below or adjacent to the ribbons 102. Light reflected from the movable ribbons 102a adds as vectors of magnitude and phase with that reflected from stationary ribbons 102b and/or a reflective portion of the surface 106 beneath the ribbons, thereby modulating light reflected from the SLM 100.

Fabricating the movable ribbons 102 includes steps of: (i) forming a sacrificial layer 112 on the surface 106 of the substrate 108; (ii) depositing and patterning a layer of elastic material, such as silicon-nitride (SiN), on the sacrificial layer to form the ribbons 102; (iii) coating a top surface of the elastic material with a reflective material; and (iv) removing all or substantially all of the sacrificial layer to partially release the ribbons from the substrate. Generally, the reflective material includes a metal or an alloy. The sacrificial layer can include silicon, which is removed in a dry etch process using an etchant gas or in a wet etch process.

Referring to FIG. 2, there are many problems with fabricating a MEMS device 200 including movable ribbons 202 using prior art methods. One problem is a common method of depositing metal using metal evaporation is unsuitable for fabricating such devices as the metal coating uniformity is very poor leading to unsatisfactory devices and low yields. In addition, these MEMS and optoelectronic devices frequently include semiconductor integrated circuits (ICs), and thus are often fabricated in semiconductor fabrication laboratories, in which metal evaporators are typically not available.

Another method commonly used to deposit metal coatings is sputtering. Sputter is a process in which atoms in a solid source material are ejected into the gas phase due to bombardment of the source material by energetic ions supplied by plasma. A bias applied to a target substrate causes the metal atoms to be deposited thereon.

One problem associated with the sputtering method is a build-up or undesired deposition of the reflective material 204 or metal on sidewalls 206 of the sacrificial layer 208 that impedes or prevents subsequent release of the ribbons 202 from the substrate 210.

Accordingly, there is a need for an improved method for fabricating nano-scale and micro-scale electromechanical devices that is compatible with IC fabrication and substantially eliminates undesired build-up of the metal or reflective material on sidewalls of a sacrificial layer.

### SUMMARY OF THE INVENTION

The present invention provides a solution to these and other problems, and offers further advantages over conventional fabrication processes and methods.

In one aspect, the present invention is directed to a method for fabricating a micro-electromechanical device. Generally, the method includes steps of: (i) forming a device layer over a sacrificial layer on a surface of a substrate; (ii) patterning the device layer to form a number of ribbons each including a long axis parallel to the surface of the substrate and a middle section between support structures at both ends of the ribbon; (iii) partially removing the sacrificial layer to undercut the number of ribbons; (iv) forming a reflective coating of a reflective material on the number of ribbons; and (v) releasing the middle section of at least one of the number of ribbons by removing the sacrificial layer. It will be appreciated that undercutting or partially releasing the number of ribbons prior to forming the reflective coating reduces build-up of the reflective material on sidewalls of the sacrificial layer facilitating release of the ribbons. Preferably, the step of patterning the device layer comprises the step of forming a plurality of channels extending through the device layer and the sacrificial layer to the surface of the substrate. More preferably, the step of partially removing the sacrificial layer comprises the step of undercutting the number of ribbons by removing from about 10 to about 90% of the sacrificial material under the middle section thereof.

In certain embodiments, the step of forming a reflective coating on the ribbons comprises the step of depositing a metal by sputtering, and the method further comprises the step of removing any metal deposited on sidewalls of the sacrificial layer prior to releasing the ribbons. Undesired metal deposited on sidewalls of the sacrificial layer can be removed using a photo develop track tool or a selective wet metal etch technique.

In another other embodiment or aspect, the invention is directed to a method for fabricating a voltage controlled Micro-Electromechanical System (MEMS) device. Generally, the method includes steps of: (i) forming a device layer over a sacrificial layer on a surface of a substrate; (ii) patterning the device layer to form a number of ribbons each including a long axis parallel to the surface of the substrate and a middle section between support structures at both ends of the ribbon; (iii) partially removing the sacrificial layer to undercut the number of ribbons; (iv) depositing a metallic material on top surfaces of the number of ribbons to form first electrodes thereon; and (v) releasing the middle section of at least one of the number of ribbons by removing the sacrificial layer. Again, undercutting the ribbons prior to depositing the metallic material reduces deposition of the metallic material on sidewalls of the sacrificial layer facilitating release of the ribbons.

In certain preferred versions of this embodiment, the step of patterning the device layer comprises the step of forming a plurality of channels extending through the device layer and the sacrificial layer to the surface of the substrate, and the step of depositing a metallic material includes the step of depositing metallic material on regions of the surface of the substrate exposed by the plurality of channels to form second electrodes thereon.

Optionally, the method can further include the step of removing any metallic material deposited on sidewalls of the sacrificial layer prior to removal thereof using a photo develop track tool or a selective wet metal etch technique.

The above methods are particularly useful for fabricating ribbon-type spatial light modulator (SLMs) wherein the device layer includes a tensile silicon-nitride (SiN) layer formed over a polysilicon sacrificial layer, and metal is deposited on top surfaces of the ribbons to form a reflective surface and first electrodes thereon.

### BRIEF DESCRIPTION OF THE DRAWINGS

These and various other features and advantages of the present invention will be apparent upon reading of the following detailed description in conjunction with the accompanying drawings and the appended claims provided below, where:

FIG. 1 is a perspective view of a ribbon-type spatial light modulator (SLM);

FIG. 2 is a block diagram of an intermediate structure illustrating partially released ribbons of a micro-electromechanical systems (MEMS) device including a reflective coating formed thereon by a conventional method and exhibiting undesirable sidewall deposition;

FIG. 3 is a flow chart illustrating a method for fabricating a MEMS device including a ribbon with a reflective coating formed thereon according to an embodiment of the present invention;

FIG. 4 is a block diagram of an intermediate structure illustrating partially released ribbons of a MEMS device including a reflective coating formed thereon according to an embodiment of the present invention; and

FIG. 5 is a block diagram of the intermediate structure of FIG. 4 following a selective wet metal etch according to an embodiment of the present invention and exhibiting substantially no undesirable sidewall deposition.

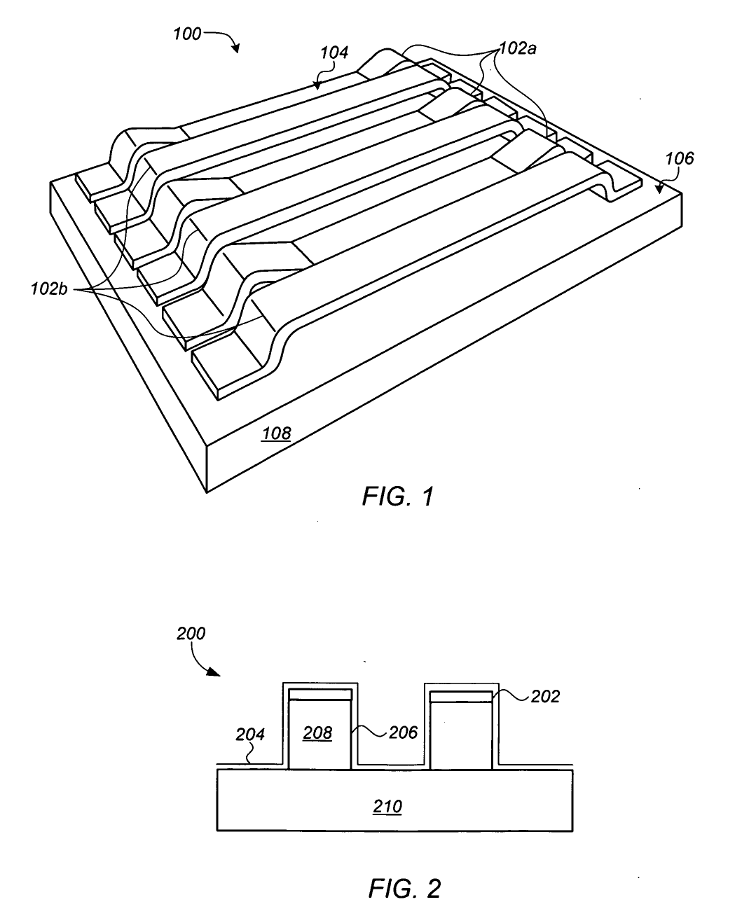

### DETAILED DESCRIPTION

The present invention is directed to a method for manufacturing micro-scale and nano-scale electromechanical devices, such as micro-electromechanical systems (MEMS) and integrated circuits (ICs), including structures with metal or reflective coatings formed thereon.

The method of the present invention is particularly useful for manufacturing optoelectronic devices, such as ribbon-type spatial light modulators (SLMs).

In the following description, for purposes of explanation, numerous specific details are set forth in order to provide a thorough understanding of the present invention. It will be evident, however, to one skilled in the art that the present invention may be practiced without these specific details. In other instances, well-known structures, and techniques are not shown in detail or are shown in block diagram form in order to avoid unnecessarily obscuring an understanding of this description.

Reference in the description to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

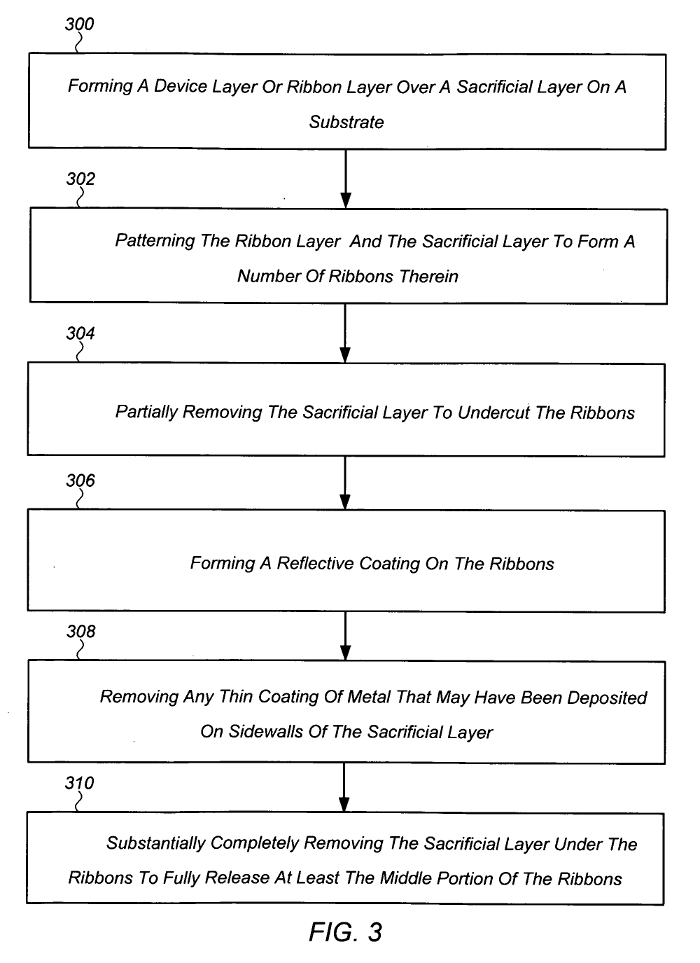

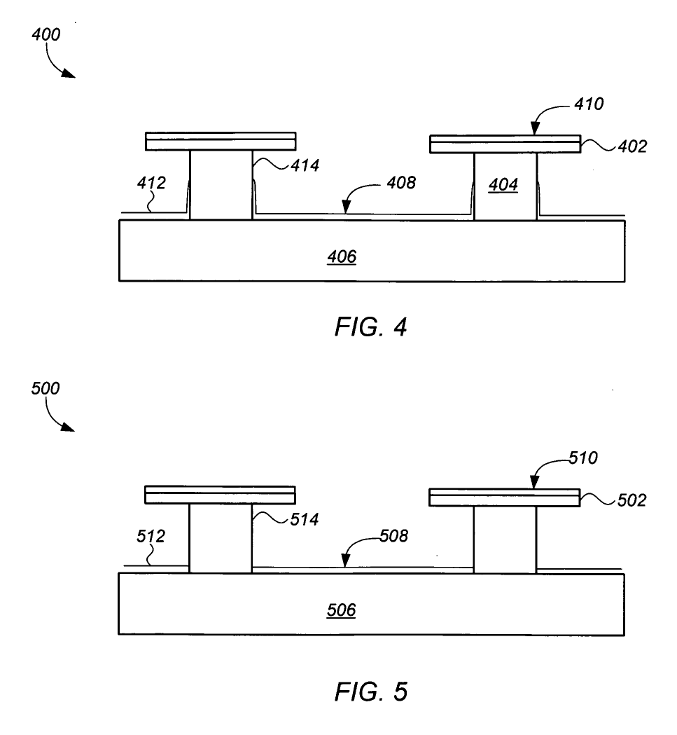

An exemplary method fabricating a MEMS device including a structure with a reflective coating formed thereon will now be described with reference to FIGS. 3 through 5, where FIG. 3 is a flow chart of one embodiment of the method, and FIGS. 4 and 5 are block diagrams of an intermediate structure illustrating a partially released ribbon of a MEMS device including a reflective coating formed thereon according to an embodiment of the present invention.

Referring to FIG. 3, in one embodiment the method of the present invention begins with forming a device layer or ribbon layer over a sacrificial layer on a substrate (step 300). Next, the ribbon layer and the sacrificial layer are patterned to form a number of ribbons therein (step 302). Each ribbon includes a long axis parallel to a surface of the substrate and a middle section between support structures at both ends of the ribbon. The sacrificial layer is then partially removed to undercut the number of ribbons (step 304). Next, a reflective coating, such as a thin layer of a reflective material, such as a metal, is formed on the ribbons (step 306). Any thin coating or small amount of reflective material that may have been deposited on sidewalls of the sacrificial layer is then removed (step 308). Finally, the sacrificial layer under the ribbons is substantially completely removed to fully release at least the middle portion of the ribbons (step 310). It will be appreciated by those skilled in the art that undercutting the ribbons reduces undesired build-up of the reflective material or metal on sidewalls of the sacrificial layer, thereby facilitating subsequent removal of the sacrificial layer and release of the ribbons.

The above method yields the intermediate structure shown or illustrated in FIG. 4. Referring to FIG. 4, the intermediate structure 400 generally includes one or more ribbons 402 formed over a partially removed sacrificial layer 404 on a substrate 406, and reflective surfaces 408, 410, formed on top or upper surfaces of the substrate and the ribbons respectively by depositing a reflective coating 412 using the above described method. Optionally or preferably, the reflective coating 412 is a metallic material or metal that also serves to form upper and/or lower electrodes to electro-statically deflect the ribbons 402 towards the substrate 406 using integrated drive electronics (not shown) formed in or on the surface of the substrate. As noted above, undercutting reduces or substantially eliminates undesired build-up of the reflective material on sidewalls 414 of the sacrificial layer 404.

The materials and steps of the above method will now be described in greater detail.

Generally, the substrate can be a wafer of any material suitable for the manufacture of microelectronic devices. Suitable materials include, for example, silicon, gallium-arsenide, lithium-tantalate crystal, and other such semiconducting and dielectric materials used in the manufacture of MEMS, ICs and/or semiconductor devices.

The sacrificial layer can be any suitable material that is non-reactive or non-detrimental to the materials of the substrate, the circuits or circuit elements and the overlying device layer, and is capable of being removed or released by processing chemistry having a high selectivity to the material of the sacrificial layer relative to these other layers. The sacrificial layer may or may not be planarized. Planarization of the sacrificial layer can be accomplished, for example, by chemical mechanical polishing or planarization (CMP). Preferably, the sacrificial layer includes amorphous silicon, which is transformed in subsequent processing steps to polycrystalline silicon or polysilicon, and may be removed or released by a dry or wet etch chemistry with a high selectivity to the material of the device layer as described below.

The material of the overlying device or ribbon layer, which is patterned to form the ribbon or at least one feature of the micro-device, is selected to provide desired mechanical and electrical or dielectric properties for the feature. Although not shown it will be appreciated that the device layer may include a stack of multiple layers of conducting, semi-conducting and insulating or dielectric material. For example, in the embodiment shown in FIG. 4 in which the micro-device is a ribbon-type SLM and the features formed the device layer include one or more ribbons, the device layer overlying the sacrificial material can include a tensile silicon-nitride (SiN) layer. The device or ribbon layer is patterned using standard photolithographic and etching techniques to form the features or ribbons. The specific techniques used will depend on the materials selected for the device layer and the sacrificial layer. For example, where the device layer includes a SiN layer overlying a poly sacrificial layer, a photoresist mask can be formed on the surface of the device layer, and the pattern transferred to the device layer by removing exposed portions thereof using a suitable etch process.

One suitable process for etching the SiN layer is a dry etch including a first etch step using C₂F₆/He, followed by second etch in a carbon-fluoride chemistry of the form CL₂/He or CL₂/He/SF₆, such as methyl fluoride (CH₃F). Preferably, the nitride etch has a selectivity of nitride with respect to the underlying poly sacrificial layer of at least about 3:1, and more preferably of about 5:1 or more. More preferably, the silicon-nitride is covered by a photo-resist or resist, and the exposed area of the silicon-nitride is etched with C₂F₆/He.

As noted above, the sacrificial layer is partially removed or released to undercut the ribbons or features formed in the device layer using a dry or wet etch chemistry. One exemplary dry etch chemistry used for partial release can include Sulfur hexafluoride (SF₆) and Helium (He) chemistry, which provides an isotropic Poly-silicon etch with high selectivity to many films such as: silicon-nitride, resist, and Aluminum. Another example of a dry etch chemistry that may be used for partial release can include Xenon difluoride (XeF₂) sublimated in a container or vessel to a pressure of about 4 mTorr (the vapor pressure of XeF₂), and then introduced as a vapor into a separate etch chamber in which the substrate is positioned. Alternatively, the sacrificial layer may be partially or completely removed in a single wafer wet processing tool, commercially available from SEZ Group, of Villach, Austria, or in a wet processing bath or sink using a mixed nitric acid (HNO₃) and HF wet chemistry.

The reflective coating can include any suitable reflective material, such as a metal, having the desired optical, mechanical and/or electrical properties, and can be formed or deposited on the top or upper surfaces of the ribbons and the substrate using sputtering, evaporation, or any other suitable physical vapor deposition technique. For example, in one embodiment the reflective coating can include a thin layer of metal, such as aluminum (Al) or an aluminum-copper (AlCu) alloy, deposited using thermal, electron-beam or resistive evaporation. Evaporation is a process wherein the energy of atoms or molecules in a solid source material is raised sufficiently to enter the gaseous state, and from which they are allowed to condense and deposit on surfaces in an enclosed chamber, including the target wafer or substrate.

In a preferred embodiment, the reflective coating includes a thin layer of metal, such as Al or AlCu formed sputtering or deposited using sputtering techniques, which due to the bias applied to a target wafer or substrate is more directional or isotropic in nature. Sputter is a process in which atoms in a solid source material are ejected into the gas phase due to bombardment of the source material by energetic ions supplied by plasma in the sputtering tool, and application of a bias voltage to the target substrate. Commonly the plasma is formed utilizing a RF (radio frequency) alternating current and a magnetic field.

The metal deposition is followed by a selective wet metal etch to remove any thin coating or small amount of metal that may have been deposited on sidewalls of the sacrificial layer. By selective wet metal etch it is meant an etch in which the etch chemistry preferentially attacks and removes the metal substantially without etching the adjoining material of the device layer, sacrificial layer or substrate, thereby yielding the intermediate structure shown in FIG. 5. Preferably, the selective wet metal etch uses a weakly basic solution or chemistry, which provides a controlled, slow etch rate of from about 10 Å/min to about 100 Å/minute that removes metal on the sidewalls while maintaining a smooth, optically reflective surface on the reflective coating on the ribbons. In one embodiment, the selective wet metal etch is performed using any commercially available developer solution, since all such developers are weakly basic. One suitable developer is a tetramethylammonium hydroxide (TMAH) developer commercially available from JSR Micro Inc., of Sunnyvale Calif., which provides an etch rate of about 65 Å/min. Alternatively, a weak base such as ammonium-hydroxide (NH₄OH) can also be used.

More preferably, the selective wet metal etch is performed or carried out by running the substrate with the intermediate ribbon structure formed thereon through a photo develop track tool, such as a SVG® tool available from ASML, of Veldhoven, the Netherlands, a DNS™ Developer available from Siconnex, of Salzburg, Austria, or a FSI™ Developer available from FSI International Inc., of Milpitas Calif. The precise process control of the photo develop track tool is superior to that which can be obtained using a wet bench or immersion bath. This is desirable since controlling the thickness of the thin Al film coating the ribbon surface is important to ensure proper working of the device.

Alternatively, where the reflective coating includes Al or AlCu, the undesired metal can be removed by processing in a wet metal etch bath using a commercially available aluminum etchant to remove on sidewalls of the sacrificial layer. One suitable aluminum etchant is that available from Ashland Specialty Chemical Company of Covington, Ky., and comprising phosphoric acid, nitric acid, acetic acid and deionized water mixed in a ratio of about 16:1:1:2. Preferably, the standard aluminum etchant is further diluted using deionized water to provide a controlled etch rate within the range of from about 10 Å/min to about 100 Å/min. Optionally, the etching solution may be heated, for example to a temperature of about 40° C., to provide additional control over the etch rate of the process.

Referring to FIG. 5, the intermediate structure 500 generally includes one or more ribbons 502 formed over a partially removed sacrificial layer 504 on a substrate 506, and reflective surfaces 508, 510, formed on top or upper surfaces of the substrate and the ribbons respectively. As noted above, undercutting the ribbons 502 prior to forming the reflective surfaces 508, 510 substantially eliminates undesired build-up of the reflective material on sidewalls 514 of the sacrificial layer 504.

Following this the middle section of at least one of the number of ribbons 502 is fully released by substantially removing the entire sacrificial layer thereunder. The sacrificial layer can be removed using a dry or wet etch chemistry as noted above.

The advantages of the method of the present invention over previous or conventional approaches include reducing or substantially eliminating undesired build-up of the reflective material or metal on sidewalls of the sacrificial layer during formation of the reflective coating, thereby facilitating subsequent removal of the sacrificial layer and release of the ribbons. The process or method of the present invention is fully compatible with and can be integrated into existing process flows, including those in which the reflective coating is formed using evaporation or sputtering techniques.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. In particular, it will be understood that dimensions shown in the accompanying figures, while suitable for fabricating ribbon-type SLMs, are exemplary only, and it is not intended that the invention be limited thereby. It is intended that the scope of the invention encompass the generic area as herein disclosed, and by the claims appended hereto and their equivalents. The scope of the present invention is defined by the claims, which includes known equivalents and unforeseeable equivalents at the time of filing of this application.

What is claimed is:

1. A method for fabricating a micro-electromechanical device comprising steps of:
forming a device layer over a sacrificial layer on a surface of a substrate;
patterning the device layer to form a number of ribbons each including a long axis parallel to the surface of the substrate and a middle section between support structures at both ends of the ribbon;
partially removing the sacrificial layer to undercut the number of ribbons;
forming a reflective coating of a reflective material on the number of ribbons; and
releasing the middle section of at least one of the number of ribbons by removing the sacrificial layer,
whereby undercutting the number of ribbons prior to forming the reflective coating reduces build-up of the reflective material on sidewalls of the sacrificial layer facilitating release of the ribbons.

2. A method according to claim 1, wherein the step of patterning the device layer comprises the step of forming a plurality of channels extending through the device layer and the sacrificial layer to the surface of the substrate.

3. A method according to claim 1, wherein the step of partially removing the sacrificial layer comprises the step of undercutting the number of ribbons by removing from about 10 to about 90% of the sacrificial material under the middle section thereof.

4. A method according to claim 1, wherein the step of forming a reflective coating on the ribbons comprises the step of depositing a metal.

5. A method according to claim 4, wherein the step of forming a reflective coating on the ribbons comprises the step of depositing the metal by sputtering, and further comprising the step of prior to fully releasing the middle section of at least one of the number of ribbons removing metal deposited on sidewalls of the sacrificial layer using a selective wet metal etch.

6. A method according to claim 4, wherein the step of forming a reflective coating on the ribbons comprises the step of depositing the metal by sputtering, and further comprising the step of prior to fully releasing the middle section of at least one of the number of ribbons removing any metal deposited on sidewalls of the sacrificial layer using a photo develop track tool.

7. A method according to claim 1, wherein the micro-electromechanical device is a ribbon-type spatial light modulator (SLM).

8. A method according to claim 7, wherein the device layer comprises a tensile silicon-nitride (SiN) layer.

9. A method for fabricating a voltage controlled Micro-Electromechanical System (MEMS) device comprising steps of:
forming a device layer over a sacrificial layer on a surface of a substrate;
patterning the device layer to form a number of ribbons each including a long axis parallel to the surface of the substrate and a middle section between support structures at both ends of the ribbon;
partially removing the sacrificial layer to undercut the number of ribbons;
depositing a metallic material on top surfaces of the number of ribbons to form first electrodes thereon; and
releasing the middle section of at least one of the number of ribbons by removing the sacrificial layer,
whereby undercutting the number of ribbons prior to depositing the metallic material reduces deposition of the metallic material on sidewalls of the sacrificial layer facilitating release of the ribbons.

10. A method according to claim 9, wherein the step of patterning the device layer comprises the step of forming a plurality of channels extending through the device layer and the sacrificial layer to the surface of the substrate, and wherein the step of depositing a metallic material comprises the step of depositing metallic material on regions of the surface of the substrate exposed by the plurality of channels to form second electrodes thereon.

11. A method according to claim 9, wherein the step of partially removing the sacrificial layer comprises the step of undercutting the number of ribbons by removing from about 10 to about 90% of the sacrificial material under the middle section thereof.

12. A method according to claim 9, wherein the step of depositing a metallic material comprises the step of depositing a metal by sputtering, and further comprising the step of prior to fully releasing the middle section of at least one of the number of ribbons removing metal deposited on sidewalls of the sacrificial layer using a selective wet metal etch.

13. A method according to claim 9, wherein the step of depositing a metallic material comprises the step of depositing the metal by sputtering, and further comprising the step of prior to fully releasing the middle section of at least one of the number of ribbons removing metal deposited on sidewalls of the sacrificial layer using a photo develop track tool.

14. A method according to claim 9, wherein the voltage controlled MEMS device is a ribbon-type spatial light modulator (SLM).

15. A method according to claim 14, wherein the device layer comprises a tensile silicon-nitride (SiN) layer.

16. A method for fabricating a ribbon-type spatial light modulator (SLM) comprising steps of:
forming a tensile silicon-nitride (SiN) layer over a polysilicon sacrificial layer on a surface of a substrate;
patterning the SiN layer to form a number of ribbons each including a long axis parallel to the surface of the substrate and a middle section between support structures at both ends of the ribbon;
partially removing the sacrificial layer to undercut the number of ribbons;
depositing a metal on top surfaces of the number of ribbons to form first electrodes thereon; and
releasing the middle section of at least one of the number of ribbons by removing the sacrificial layer,
whereby undercutting the number of ribbons prior to depositing the metal reduces deposition of the metal on sidewalls of the sacrificial layer facilitating release of the ribbons.

17. A method according to claim 16, wherein the step of patterning the tensile silicon-nitride layer comprises the step of forming a plurality of channels extending through the silicon-nitride layer and the sacrificial layer to the surface of the substrate, and wherein the step of depositing a metal comprises the step of depositing metal on regions of the surface of the substrate exposed by the plurality of channels to form second electrodes thereon.

18. A method according to claim 16, wherein the step of partially removing the sacrificial layer comprises the step of undercutting the number of ribbons by removing from about 10 to about 90% of the sacrificial material under the middle section thereof.

19. A method according to claim 16, further comprising the step of prior to fully releasing the middle section of at least one of the number of ribbons removing metal deposited on sidewalls of the sacrificial layer using a selective wet metal etch.

20. A method according to claim 16, further comprising the step of prior to fully releasing the middle section of at least one of the number of ribbons removing metal deposited on sidewalls of the sacrificial layer using a photo develop track tool.
